(19) United States
(12) Patent Application Publication
(10) Pub. No.: US 2004/0258842 A1
(43) Pub. Date: Dec. 23, 2004

(54) Coated member and method of manufacture

(76) Inventor: Noriaki Hamaya, Takefu-shi (JP)

Correspondence Address: BIRCH STEWART KOLASCH & BIRCH, PO BOX 747, FALLS CHURCH, VA, 22040-0747, US

(21) Appl. No.: 10/868,785

(22) Filed: Jun. 17, 2004

(30) Foreign Application Priority Data
Jun. 19, 2003 (JP) 2003-174390

(51) Int. Cl. C23C 16/00

(52) U.S. Cl. 427/409; 427/446; 427/256; 428/408; 428/632

(57) ABSTRACT

By thermal spraying, a coating having an embossed or slit pattern is formed on a substrate to construct a coated member. When the coated member is used for sintering compacts, the embossed or slit pattern on the surface helps prevent the compacts from sticking to the coated member during sintering, discourages coating separation due to thermal cycling, and provides the coated member with excellent durability. Such coated members can be effectively used for sintering or heat treating ceramics and powder metallurgy metals, particularly cermets and cemented carbides, in a vacuum, oxidizing atmosphere, inert atmosphere or reducing atmosphere.

### TECHNICAL FIELD

The present invention relates in particular to heat-resistant coated members used when sintering or heat treating powder metallurgy metals, cemented carbides, cermets or ceramics in a vacuum, an oxidizing atmosphere, an inert atmosphere or a reducing atmosphere. The invention also relates to a method of manufacturing such coated members.

### BACKGROUND ART

Powder metallurgy and manufacturing processes for ceramics and related materials generally include a firing or sintering step, and also a heat treatment step. In these steps, the green body from which the final product is to be made is typically set on a tray. However, the tray materials sometimes react with the product, causing distortion, deviations in composition and the uptake of impurities, lowering the yield of the fired or sintered product. One way to prevent reactions between the tray and the product is to use an oxide powder such as alumina or yttria or a nitride powder such as aluminum nitride or boron nitride as a placing powder on the tray. Another way is to mix such an oxide or nitride powder with an organic solvent, and coat or spray the resulting slurry onto the tray to form a protective coating. However, these approaches have a number of drawbacks. For example, when a placing powder is used, the powder may adhere to the surface of the product. If a slurry coat has been applied to the tray, the coating may separate from the substrate, making it necessary to repeat the same coating operation after only one or a small number of uses.

One solution to these problems is proposed in JP-A 2000-509102, which describes the formation of a dense coating on the surface of a tray by a process such as thermal spraying.

This technique is effective for preventing the tray from reacting with the product. However, with repeated thermal cycling, the interface between the thermal sprayed coating and the tray substrate thermally degrades, allowing the coating to readily separate from the substrate. A need thus exists for coated members which are heat resistant, corrosion resistant, durable and non-reactive, and in which separation of the thermally sprayed coating from the substrate does not occur even with repeated thermal cycling.

### SUMMARY OF THE INVENTION

It is therefore one object of the present invention to provide highly heat-resistant, corrosion-resistant and non-reactive coated members which, when used for sintering or heat treating powder metallurgy metals, cemented carbides, cermets or ceramics in a vacuum, oxidizing atmosphere, inert atmosphere or reducing atmosphere, are not readily subject to coating separation under thermal cycling and thus have an excellent durability. Another object of the invention is to provide a method of manufacturing such coated members.

We have found that heat-resistant coated members ARE obtained by forming on a substrate a coating of an oxide or other suitable material having an embossed or slit (textured) surface, and that particularly when used in the sintering or heat treatment of powder metallurgy metals, cermets or ceramics in a vacuum, oxidizing atmosphere, inert atmosphere or reducing atmosphere, the coated members have an excellent heat resistance, are not readily subject to separation under repeated thermal cycling, and thus have a good durability. Moreover, they do not react with the product being sintered or heat treated, and thus help prevent sticking.

Accordingly, in one aspect, the invention provides a coated member comprising a substrate and a coating which is formed on the substrate and has an embossed or slit pattern. The embossed or slit pattern has raised areas with individual heights of preferably 0.02 to 0.5 mm and with gaps therebetween at intervals of preferably 0.02 to 5 mm.

In this coated member, the coating which has an embossed or slit pattern is typically an oxide coating, and preferably one containing a rare earth oxide. The substrate in the coated member is typically made of carbon.

The coating which has an embossed or slit pattern is typically a thermal sprayed coating and, in one preferred embodiment of the invention, is formed on the substrate by thermal spraying over an intervening thermal sprayed under coat.

The coated member of the invention is typically used for sintering a powder metallurgy metal, cemented carbide, cermet or ceramic in a vacuum, an oxidizing atmosphere, an inert atmosphere or a reducing atmosphere.

In a second aspect, the invention provides a method of manufacturing coated members, which method includes using a thermal spraying process to form a coating having an embossed or slit pattern on a substrate.

In a preferred embodiment, the inventive method of manufacturing coated members includes the steps of using a thermal spraying process to form an under coat over the entire substrate, then forming a coating having an embossed or slit pattern on the under coat.

Thermal spraying is preferably carried out through spaces in a grid, mesh or slit-type patterning mask to form a coating having an embossed or slit pattern in a shape that corresponds to the spaces in the mask.

### BRIEF DESCRIPTION OF THE DRAWINGS

The objects, features and advantages of the invention will become more apparent from the following detailed description, taken in conjunction with the accompanying drawings.

FIG. 1 shows a coated member according to one embodiment of the invention. FIG. 1A is a plan view of the coated member, FIG. 1B is a partial, enlarged, plan view, and FIG. 1C is a cross-sectional view along line B-B in FIG. 1B.

FIG. 2 is a plan view of a coated member according to another embodiment of the invention.

FIG. 3 is a plan view of a coated member according to yet another embodiment of the invention.

FIG. 4 shows a method of manufacturing coated members according to one embodiment of the invention in which a patterning mask is used. FIG. 4A is a plan view, and FIG. 4B is a cross-sectional view along line A-A in FIG. 4B.

### DETAILED DESCRIPTION OF THE INVENTION

The heat-resistant coated member of the invention is composed of a substrate and a coating, preferably an oxide coating which is formed on the substrate and has an embossed or slit pattern. A product is typically placed on the coated member and subjected to heat treatment such as firing or sintering. The heat-resistant coated member of the invention is used particularly when carrying out the sintering or heat treatment of a powder metallurgy metal, cermet or ceramic in a vacuum, an oxidizing atmosphere, an inert atmosphere or a reducing atmosphere to form a product. Examples of such coated members include setters, saggers, trays and molds.

In the practice of the invention, examples of suitable substrates for manufacturing such heat-resistant, corrosion-resistant and durable coated members for use in the sintering or heat treatment of powder metallurgy metals, cermets, cemented carbides and ceramics include carbon, heat-resistant metals such as molybdenum, tantalum, tungsten, zirconium and titanium, alloys of these metals, oxide ceramics such as alumina and mullite, carbide ceramic such as silicon carbide and boron carbide, and nitride ceramics such as silicon nitride. Of these, carbon is especially preferred from the standpoint of heat resistance, durability and workability.

An oxide coating or other suitable coating having a textured surface with an embossed or slit pattern is formed on the substrate. The oxide coating may be made of an ordinary oxide such as alumina or zirconia, although the use of a rare earth-containing oxide such as a rare earth oxide or a rare earth-containing complex oxide is especially preferable for minimizing reactivity of the coated member with cermets and cemented carbides.

The method of forming the embossed pattern is described. The surface of the desired substrate is optionally roughened by blasting, following which an under coat of a given thickness is formed, preferably by plasma spraying, over the entire surface. After formation of the under coat, a mask bearing a pattern of a given shape, such as a grid, mesh or slit-like shape, is set over the entire under coat. If an under coat has not been formed, this mask is set directly on the substrate. A given thermal sprayed coating is then formed thereon by plasma spraying. The plasma spraying material in this case may be the same material as in the under coat or a different material. Places covered by the patterning mask do not receive a thermal sprayed coating; only those areas of the substrate or under coat corresponding to spaces in the mask pattern receive the thermal sprayed coating, thus forming an embossed or slit-like textured pattern. Patterning masks used for this purpose may be made of, for example, a screen or other type of wire mesh, or a round punched metal plate. The raised areas formed by the mask pattern may have any of various suitable surface shapes, including triangular, quadrangular, polygonal, circular or elliptical shapes.

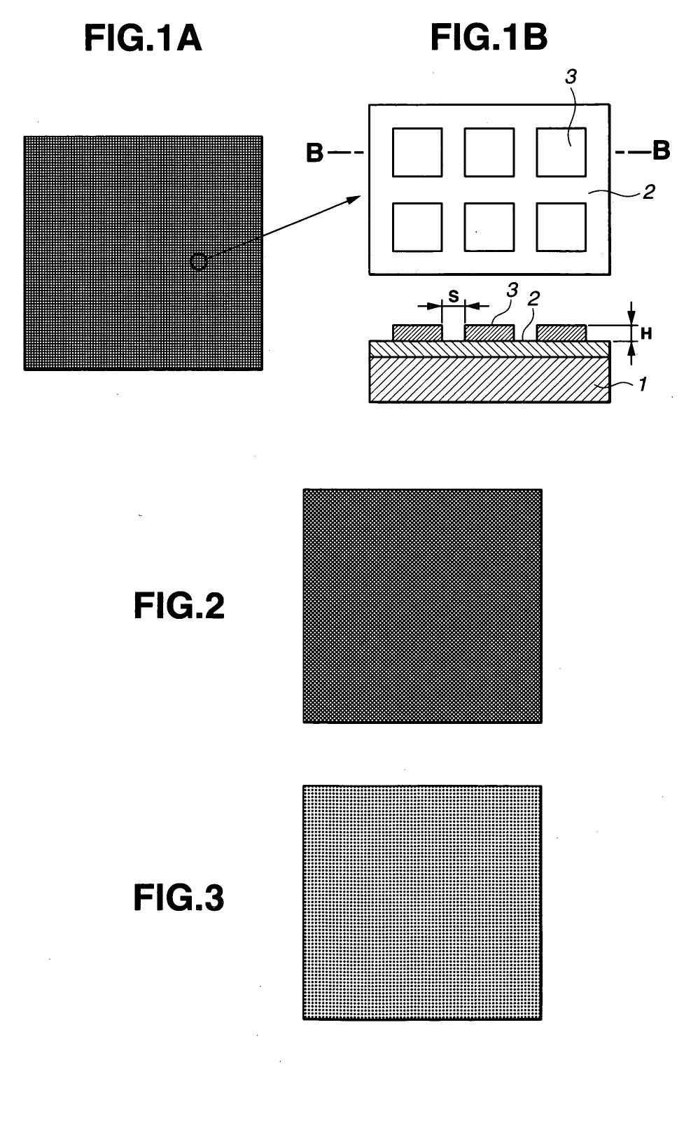

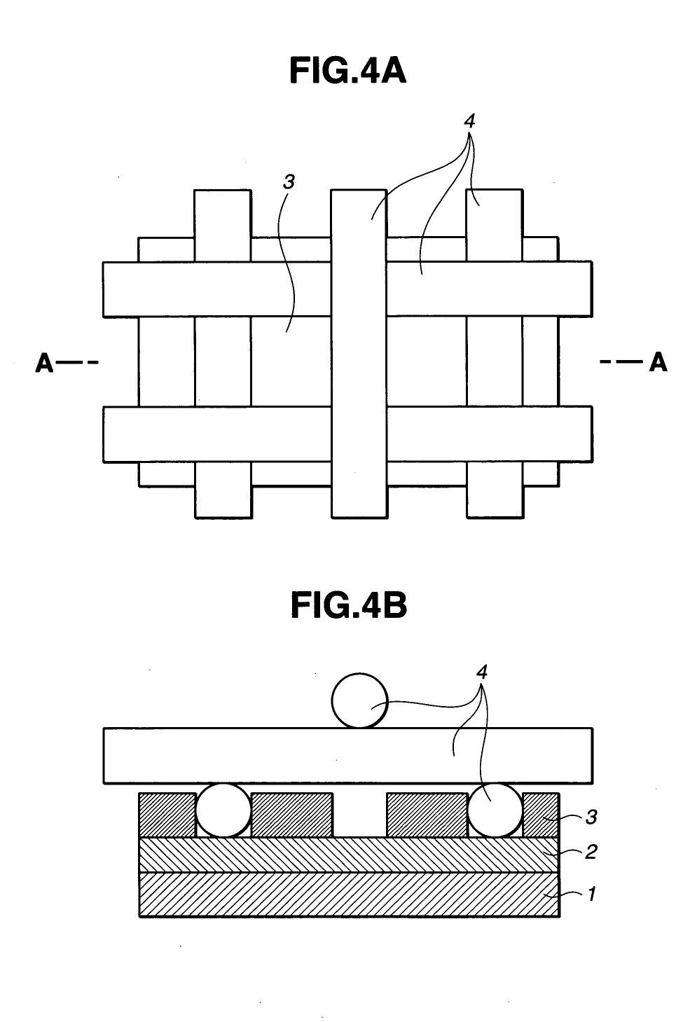

The accompanying diagrams show examples of textured surfaces having an embossed pattern produced by the foregoing method. Raised areas of various shapes can be formed on the substrate by changing the mask pattern. In the embodiment shown in FIG. 1, a coated member is composed of a substrate 1 and a thermally sprayed under coat 2 on which has been formed a coating 3 having a grid-like embossed pattern. Also shown in the diagrams are coated members on which have been formed coatings of a diamond (FIG. 2) or round (FIG. 3) embossed pattern. FIG. 4 shows a grid-like embossed pattern being formed using a mask pattern 4 like that described above.

A surface having an embossed or slit pattern can similarly be obtained by setting the patterning mask directly on the blast-roughened substrate and plasma spraying an oxide powder onto the substrate to form a specific sprayed coating. A similar embossed pattern can likewise be formed by using, instead of the oxide powder, a thermal spraying powder made of a metal or other suitable material. In addition to the formation of an embossed surface on flat areas of a substrate, by setting the patterning mask on the beveled portions of a grooved plate substrate, on the sidewalls of a cylindrical substrate, or even on curved surfaces of complex shape, this manufacturing process is also capable of easily forming an embossed or slit pattern on any of these surfaces. Moreover, the height and width of the bosses or slits in the pattern can be freely controlled by varying the thickness of the mask pattern and the width and intervals of the spaces. For example, to obtain an embossed surface with raised areas having a height of 0.5 mm, the desired embossed pattern can easily be achieved by selecting a patterned mask thickness of at least 0.5 mm and controlling the number of thermal spraying passes.

The article to be treated is placed on the textured coating of oxide or the like having an embossed or slit pattern surface formed by the above method, then fired, sintered or heat treated. By forming a surface having an embossed or slit pattern, the surface area of contact with the product is reduced, which helps to suppress sticking between the oxide coating and the product that causes coating separation. This is particularly effective when firing or sintering cermets and cemented carbides such as tungsten carbide. For example, in the cemented carbide debinding and firing steps, the binder vapor such as paraffin present in a tungsten carbide green body escapes more easily, making it possible to prevent distortion of the product. In sintering, the sticking and coating separation that arise when cobalt present in the tungsten carbide diffuses into the oxide coating can be prevented by using an embossed or slit pattern to reduce the surface area of contact. Moreover, even when coating separation does arise in areas of sticking, the surface area of such separation can be minimized. That is, coating separation can be restricted to a single raised area in the pattern. Separation of the oxide coating from the substrate thus decreases, making it possible to provide heat-resistant coated members which have a good durability to thermal cycling in the sintering of product.

The oxide or other suitable material used to form the embossed or slit pattern by thermal spraying is typically. composed of particles having a mean diameter of 10 to 70 m. The coated member of the invention is manufactured by using hydrogen gas, or an inert gas such as argon or nitrogen, to plasma spray such particles onto the substrate. As described above, if necessary, the surface of the substrate may be blasted or otherwise treated prior to thermal spraying.

In the coating having an embossed or slit pattern, the thickness of the coating in raised areas (H in FIG. 1) of the embossed or slit pattern is preferably at least 0.02 mm but not more than 0.5 mm, and more preferably from 0.05 to 0.3 mm. At less than 0.02 mm, with repeated use, the surface area of contact between the oxide coating and the product being sintered increases, which may result in sticking. On the other hand, at more than 0.5 mm, thermal shock within the coating at raised areas of the embossed or slit pattern may give rise to coating separation. The gap interval (S in FIG. 1) between raised areas of the embossed or slit pattern is preferably at least 0.02 mm but not more than 5 mm, and more preferably from 0.1 mm to 1 mm. At less than 0.02 mm, the surface area of contact between the oxide coating and the sintered product increases, which may result in sticking. At more than 5 mm, distortion of the sintered product may occur.

As mentioned above, an under coat can be formed on the substrate by a thermal spraying process. Such an under coat will have a thickness of preferably at least 0.02 mm but not more than 0.4 mm. To prevent reactions with sintered products made of, in particular, cermets or cemented carbides, it is preferable for the under coat to be an oxide film. Furthermore, to increase the bond strength between the substrate and the under coat, an interlayer such as an oxide (e.g., ZrO₂ stabilized with Y₂O₃), a heat-resistant metal, a carbide or a nitride may be provided between the substrate and the under coat. When an interlayer is provided between the substrate and the under coat, the interlayer and the under coat have a combined thickness of preferably at least 0.02 mm but not more than 0.4 mm.

It is also possible to form the embossed or slit pattern with a patterning mask directly on the substrate, without administering an under coat and an interlayer. In such a case, it is essential that the substrate and the oxide coating not react with each other. For example, when the substrate is made of carbon, of the rare earth oxides, the use of Yb₂O₃ in the oxide coating is preferred.

When using a heat-resistant coated member having an embossed or slit pattern obtained as described above, it is advantageous to heat treat or sinter suitable materials such as powder metallurgy metals or ceramics at not more than. 2,000° C., and preferably from 1,000 to 1,800° C., for 1 to 50 hours in a vacuum, an oxidizing atmosphere, an inert atmosphere or a reducing atmosphere. Inert atmospheres that may be used include argon atmospheres and nitrogen atmospheres. Reducing atmosphere that may be used include hydrogen atmospheres.

The coated member of the invention can be advantageously used as, for example, a jig in the production of any metal or ceramic that may be obtained by sintering or heat treatment. Exemplary metals and ceramics include chromium alloys, molybdenum alloys, cermets, tungsten carbide, silicon carbide, silicon nitride, titanium boride, rare earth-aluminum complex oxides, rare earth-transition metal alloys, titanium alloys, rare earth oxides, and rare earth-containing complex oxides. Use in the production of cermets, tungsten carbide, rare earth oxides, rare earth-aluminum complex oxides and rare earth-transition metal alloys is especially advantageous. More specifically, jigs and other coated members according to the invention are effective in the production of transparent ceramics such as YAG, cermets, and cemented carbides such as tungsten carbide, the production of Sm—Co alloys, Nd—Fe—B alloys and Sm—Fe—N alloys used in sintered magnets, the production of Tb—Dy—Fe alloys used in sintered magnetostrictive materials, and the production of Er—Ni alloys used in sintered regenerator materials for cryocoolers.

The heat-resistant coated members of the invention, by being provided on the surface thereof with an embossed or slit pattern, can prevent sticking during the sintering of products, are resistant to coating separation from thermal cycling, and have an excellent durability. As a result, the inventive coated members can be effectively used for sintering or heat treating ceramics, powder metallurgy metals, and particularly cermets and cemented carbides, in a vacuum, an oxidizing atmosphere, an inert atmosphere or a reducing atmosphere.

The technique of creating an embossed or slit pattern by thermal spraying through a pattering mask rather than directly working the substrate eliminates the time and effort required to work the substrate and allows the pattern shape and the height of raised areas to be freely controlled. This technique can thus be used in a wide range of applications.

### EXAMPLES

The following examples of the invention and comparative examples are provided by way of illustration, and not by way of limitation.

### Example 1

The surface of a 50×50×5 mm carbon substrate was roughened by blasting, following which Yb₂O₃ particles were plasma sprayed onto the surface with argon/hydrogen to form a 50 pm thick Yb₂O₃ under coat. Next, a 70×70×5 mm stainless steel wire mesh (length of mesh squares, 1 mm; wire diameter, 0.3 mm) was prepared as the patterning mask. The wire mesh was set on the Yb₂O₃ plasma-sprayed under coat, and Yb₂O₃ particles were plasma sprayed through the mesh with argon/hydrogen to form on the under coat an embossed pattern in which the raised areas had a square shape and a height of 100 Pm.

### Example 2

The surface of a 50×50×5 mm carbon substrate was roughened by blasting, following which tungsten particles were plasma sprayed onto the surface with argon/hydrogen as an interlayer to increase the bond strength with the carbon substrate, thereby forming a 40 μm thick metal coat. Complex oxide particles having a YAG composition containing elemental yttrium and elemental aluminum were then plasma sprayed onto the interlayer with argon/hydrogen, giving a plasma-sprayed under coat having a total thickness of 100 Mm. Next, a 70×70×5 mm stainless steel wire mesh (length of mesh squares, 0.6 mm; wire diameter, 0.3 mm) was prepared as the patterning mask. The wire mesh was set on the plasma-sprayed under coat, and complex oxide particles having a YAG composition containing elemental yttrium and elemental aluminum were plasma sprayed through the mesh with argon/hydrogen to form on the under coat an embossed pattern in which the raised areas had a square shape and a height of 60 μm.

### Comparative Example 1

The surface of a 50×50×5 mm carbon substrate was roughened by blasting, following which Yb₂O₃ particles were plasma sprayed onto the surface with argon/hydrogen, giving a Yb₂O₃ plasma-sprayed coated member having a coating thickness of 150 μm.

### Comparative Example 2

The surface of a 50×50×5 mm carbon substrate was roughened by blasting, following which tungsten particles were plasma sprayed onto the surface with argon/hydrogen as an interlayer to increase the bond strength with the carbon substrate, thereby forming a 40 μm thick metal coat. Complex oxide particles having a YAG composition containing elemental yttrium and elemental aluminum were then plasma sprayed onto the interlayer with argon/hydrogen, giving a plasma-sprayed under coat having a total thickness of 160 μm.

In each of the examples, coating thicknesses and heights of raised areas were measured on a polished section under low magnification with an electron microscope.

The specimens obtained in Examples 1 and 2 according to the invention and Comparative Examples 1 and 2 were placed in a vacuum of 10-2 torr and the temperature was raised to 1,550° C. at a rate of 400° C./h. The temperature was held at this level for 2 hours, after which heating was stopped and the system was allowed to cool. At 1,000° C., argon gas was introduced, thereby cooling the system at a rate of 500° C./h to about room temperature.

Next, 10 wtt of cobalt powder was mixed with tungsten carbide powder, and a cemented carbide compact having a diameter of 20 mm and a height of 10 mm was formed. The compact was placed at the center of the plasma-sprayed coated member that had been heat-treated at 1,550° C., then was set in a carbon heater furnace. A vacuum was drawn on the system and the temperature was raised at a rate of 400° C./h to 800° C. in a nitrogen atmosphere, following which a vacuum was again drawn and the temperature was raised further to 1,400° C. at 400° C./h under a vacuum of 10-2 torr. The temperature was held at this level for 2 hours, following which the heater was turned off and the system was allowed to cool. At 1,000° C., argon gas was introduced, thereby cooling the system further at a rate of 500° C./h to about room temperature. The same heat test was carried out repeatedly while placing a new cemented carbide compact on the coated member each time, and coating separation due to sticking between the plasma-sprayed coating and the cemented carbide sintered body was examined after each of 50 repetitions. No sticking or coating separation were observed in the embossed plasma spray-coated members fabricated in Examples 1 and 2. By contrast, after 35 tests, the cemented carbide body stuck to the plasma-sprayed coating on the coated member fabricated in Comparative Example 1, resulting in partial separation of the coating. Coating separation due to sticking similarly arose after 40 tests on the plasma spray-coated member fabricated in Comparative Example 2. These results show that providing an embossed pattern on the plasma-sprayed coating had the effect of improving durability.

Next, as illustrative applications of embossed patterns on thermal sprayed coatings, embossed patterns were formed on the beveled surfaces of grooved plates and the tendency for sticking to occur between the coating and cemented carbide was compared. The results are shown in Example 3. The results similarly obtained with an embossed thermally-sprayed pattern formed on a cylindrical curved surface are shown in Example 4.

### EXAMPLE 3

The surface of a 50×50×5 mm carbon grooved plate bearing eight grooves having a grove angle of 90° C. and a groove pitch of 5 mm was roughened by blasting, following which ZrO₂ particles containing 8 mol % Y₂O₃ were plasma sprayed onto the surface with argon/hydrogen as an interlayer to increase the bond strength with the carbon substrate, thereby forming a 40 μm thick plasma-sprayed coating. Complex oxide particles composed of Yb₂O₃ and Al₂O₃ in a 40:60 weight ratio were then plasma sprayed onto the interlayer with argon/hydrogen, thus forming on the beveled surfaces of the grooved plate a plasma-sprayed under coat having a total thickness of 100 μm. This specimen is referred to below as 3-a.

Next, a 70×70×5 mm stainless steel wire mesh (length of each side of mesh openings, 1 mm; wire diameter, 0.3 mm) was prepared as the patterning mask. The wire mesh was set on the plasma-sprayed under coat, and Dy₂O₃ particles were plasma sprayed with argon/hydrogen to form a diamond mesh-like embossed pattern having a height in the raised areas of 100 μm. This specimen is referred to below as 3-b.

Specimens 3-a and 3-b were placed in a vacuum of 10⁻² torr, following which the temperature was raised at a rate of 1,550° C. to 400° C./h. The temperature was held at this level for 2 hours, after which heating was stopped and the system was allowed to cool. At 1,000° C., argon gas was introduced, thereby cooling the system at a rate of 500° C./h to about room temperature.

Next, 10 wt % of cobalt powder was mixed with tungsten carbide powder, and a cemented carbide compact having a diameter of 7 mm and a height of 30 mm was formed. The compact was placed at the center of the plasma spray-coated member that had been heat-treated at 1,550° C., then was set in a carbon heater furnace. A vacuum was drawn on the system and the temperature was raised at a rate of 400° C./h to 800° C. in a nitrogen atmosphere, following which a vacuum was again drawn and the temperature was raised further to 1,400° C. at 400° C./h under a vacuum of 10⁻² torr. The temperature was held at this level for 2 hours, following which the heater was turned off and the system was allowed to cool. At 1,000° C., argon gas was introduced, thereby cooling the system further at a rate of 500° C./h to about room temperature. The plasma-sprayed coating and the cemented carbide sintered body were examined for sticking therebetween. No sticking was observed between the embossed plasma spray-coated member obtained as Specimen 3b and cemented carbide bodies sintered thereon. However, weak adherence was observed between the coated member obtained above as Specimen 3-a and cemented carbide bodies sintered thereon. These results demonstrate that providing a thermal sprayed coating with an embossed pattern (a textured surface having large protrusions) significantly reduces or eliminates the tendency for sticking to occur.

### EXAMPLE 4

A cylindrical carbon substrate having an outer diameter of 80 mm, an inner diameter of 70 mm and a height of 100 mm was furnished. The surface was roughened by blasting, following which a 0.5 mm thick punched metal plate containing 3 mm diameter holes arranged at a gap interval of 1 mm was wrapped around and secured to the cylinder. This specimen was set on a turntable and turned at a speed of 60 rpm, during which time Yb₂O₃ particles were plasma sprayed onto the surface with argon/hydrogen, thereby forming a round embossed pattern with raised areas having a height of 300 μm.

An embossed pattern of circular protrusions composed of an oxide coating was easily applied in this way to the curved surface of a substrate, thus demonstrating the applicability of such an embossed coating for preventing distortion and sticking in cases where product specimens having curved surfaces are fired or sintered.

Japanese Patent Application No. 2003-174390 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A coated member comprising:
a substrate and a coating which is formed on the substrate and has an embossed or slit pattern.

2. The coated member of claim 1, wherein the embossed or slit pattern has raised areas with individual heights of 0.02 to 0.5 mm.

3. The coated member of claim 1, wherein the raised areas of the embossed or slit pattern have gaps therebetween at intervals of 0.02 to 5 mm.

4. The coated member of claim 1, wherein the coating which has an embossed or slit pattern is an oxide coating.

5. The coated member of claim 4, wherein the oxide coating contains a rare earth oxide.

6. The coated member of claim 1, wherein the substrate is made of carbon.

7. The coated member of claim 1, wherein the coating which has an embossed or slit pattern is a thermal sprayed coating.

8. The coated member of claim 7, wherein the coating which has an embossed or slit pattern is formed on the substrate by thermal spraying over an intervening thermal sprayed under coat.

9. The coated member of claim 1 which is used for sintering a powder metallurgy metal, cemented carbide, cermet or ceramic in a vacuum, an oxidizing atmosphere, an inert atmosphere or a reducing atmosphere.

10. A method of manufacturing coated members, which method comprises using a thermal spraying process to form a coating having an embossed or slit pattern on a substrate.

11. The method of claim 10, comprising the steps of: using a thermal spraying process to form an under coat over the substrate, then forming the coating having an embossed or slit pattern on the under coat.

12. The method of claim 10, wherein thermal spraying is carried out through spaces in a grid, mesh or slit-type patterning mask to form the coating having an embossed or slit pattern with a shape that corresponds to the spaces in the mask.
